(19) United States
(12) Patent Application Publication
(10) Pub. No.: US 2025/0076366 A1
(43) Pub. Date: Mar. 6, 2025

(54) SEMICONDUCTOR WAFER HANDLING APPARATUS AND SEMICONDUCTOR WAFER TESTING SYSTEM

(71) Applicant: ADVANTEST Corporation, Tokyo (JP)

(72) Inventors: Aritomo Kikuchi, Tokyo (JP); Toshiyuki Kiyokawa, Tokyo (JP)

(73) Assignee: ADVANTEST Corporation, Tokyo (JP)

(21) Appl. No.: 18/816,814

(22) Filed: Aug. 27, 2024

(30) Foreign Application Priority Data
Aug. 31, 2023 (JP) 2023-141564

(51) Int. Cl. G01R 31/28; G01R 1/073

(52) U.S. Cl. CPC G01R 31/2867; G01R 1/07342

(57) ABSTRACT

A semiconductor wafer handling apparatus that moves a semiconductor wafer including a device under test (DUT) and presses a terminal of the DUT against a contactor of a probe card, the semiconductor wafer handling apparatus includes an optical probe that inputs and outputs an optical signal to and from an optical connection part of the DUT. The terminal is disposed on a first surface of the semiconductor wafer. The optical connection part is disposed on a second surface of the semiconductor wafer.

### CROSS-REFERENCE TO RELATED APPLICATIONS

The present application claims priority to Japanese Patent Application No. 2023-141564, filed Aug. 31, 2023. The contents of this application are incorporated herein by reference in their entirety.

### BACKGROUND

### Technical Field

The present invention relates to a semiconductor wafer handling apparatus that handles a semiconductor wafer for testing a circuit element to be tested (DUT: Device Under Test) formed in the semiconductor wafer and a semiconductor wafer testing system that tests the DUT formed in the semiconductor wafer.

### Discussion of the Background

A wafer testing system that holds a semiconductor wafer by a wafer chuck and contacts the semiconductor device formed in the semiconductor with a probe of the probe card to test the electrical properties of the semiconductor device is known (refer to, for example, Patent Document 1).

### Patent Document

PATENT DOCUMENT 1: JP 2007-129090 A

The above-described semiconductor wafer testing system is configured to test a DUT that includes only an electrical circuit and cannot test a DUT that includes an optical circuit in addition to the electrical circuit.

### SUMMARY

One or more embodiments provide a semiconductor wafer handling apparatus and a semiconductor wafer testing system for testing a DUT including an electrical circuit and an optical circuit.

An aspect 1 of one or more embodiments is a semiconductor wafer handling apparatus that moves a semiconductor wafer in which a device under test (DUT) is formed and presses a terminal of the DUT against a contactor of a probe card, the terminal being disposed on a first surface of the semiconductor wafer, the semiconductor wafer handling apparatus comprising: an optical probe that inputs and outputs an optical signal to and from an optical connection part of the DUT, the optical connection part being disposed on a second surface of the semiconductor wafer.

An aspect 2 of one or more embodiments may be the semiconductor wafer handling apparatus of the aspect 1, wherein the semiconductor wafer handling apparatus may comprise: a first moving device that relatively moves the optical probe with respect to the semiconductor wafer.

An aspect 3 of one or more embodiments may be the semiconductor wafer handling apparatus of the aspect 2, wherein the semiconductor wafer handling apparatus may comprise: a holding member that holds the semiconductor wafer; and a second moving device that relatively moves the holding member with respect to the probe card, and the first moving device may relatively move the optical probe with respect to the semiconductor wafer held by the holding member.

An aspect 4 of one or more embodiments may be the semiconductor wafer handling apparatus of the aspect 3, wherein the semiconductor wafer handling apparatus may comprise: a contact member that contacts the second surface of the semiconductor wafer; and a third moving device that relatively moves the contact member and the first moving device with respect to the semiconductor wafer held by the holding member.

An aspect 5 of one or more embodiments may be the semiconductor wafer handling apparatus of the aspect 4, wherein the contact member may comprise: a contact surface that contacts the second surface of the semiconductor wafer; and a recess that opens to the contact surface, and the optical probe may be inserted in the recess so that the optical probe is relatively movable with respect to the contact member.

An aspect 6 of one or more embodiments may be the semiconductor wafer handling apparatus of the aspect 4, wherein the contact member may comprise: a contact surface that contacts the second surface of the semiconductor wafer; and an insertion that opens to the contact surface, and the optical probe may be inserted in the insertion hole so that the optical probe is relatively movable with respect to the contact member.

An aspect 7 of one or more embodiments may be the semiconductor wafer handling apparatus of any one of the aspects 4 to 6, wherein the third moving device may comprise a support member to which the contact member and the first moving device are fixed, and the first moving device may relatively move the optical probe with respect to the contact member.

An aspect 8 of one or more embodiments may be the semiconductor wafer handling apparatus of any one of the aspects 4 to 7, wherein the semiconductor wafer handling apparatus may comprise: a controller that controls the second and third moving devices, and the controller may control the second and third moving devices to bring the holding member and the contact member closer to the probe card in a pressing direction of the DUT against the probe card and to press the terminal of the DUT against the contactor of the probe card.

An aspect 9 of one or more embodiments may be the semiconductor wafer handling apparatus of any one of the aspects 4 to 8, wherein the contact member may comprise a contact surface that contacts the second surface of the semiconductor wafer, the contact surface may have a size capable of contacting the N DUTs among the plurality of DUTs formed in the semiconductor wafer, the semiconductor wafer handling apparatus may comprise: the N optical probes disposed to correspond to the N DUTs; and the N first moving devices that move the N optical probes independently of each other, and the N may be a natural number greater than or equal to 1 and less than or equal to 8.

An aspect 10 of one or more embodiments may be the semiconductor wafer handling apparatus of the aspect 9, wherein the third moving device may relatively move the contact member and the N first moving device with respect to the semiconductor wafer held by the holding member.

An aspect 11 of one or more embodiments may be the semiconductor wafer handling apparatus of any one of the aspects 3 to 10, wherein the holding member may hold an outer peripheral part of the second or first surface of the semiconductor wafer while exposing the first and second surfaces of the semiconductor wafer.

An aspect 12 of one or more embodiments may be the semiconductor wafer handling apparatus of any one of the aspects 3 to 11, wherein the holding member may comprise an annular holding part that holds an outer peripheral part of the second or first surface of the semiconductor wafer.

An aspect 13 of one or more embodiments may be the semiconductor wafer handling apparatus of any one of the aspects 1 to 12, wherein the optical probe may comprise an optical transmission path that transmits an optical signal.

An aspect 14 of one or more embodiments may be the semiconductor wafer handling apparatus of any one of the aspects 1 to 13, wherein the optical connection part may include a grating coupler.

An aspect 15 of one or more embodiments may be the semiconductor wafer handling apparatus of any one of the aspects 1 to 14, wherein the semiconductor wafer handling apparatus may comprise: at least one of a heating device and a cooling device, the heating device may heat the DUT via the contact member, and the cooling device may cool the DUT via the contact member.

An aspect 16 of one or more embodiments is a semiconductor wafer testing system that tests a device under test (DUT) formed in a semiconductor wafer, comprising: a probe card that inputs and outputs an electrical signal to and from a terminal of the DUT, the terminal being disposed on a first surface of the semiconductor wafer; an optical probe that inputs and outputs an optical signal to and from an optical connection part of the DUT, the optical connection part being disposed on a second surface of the semiconductor wafer; and a testing device that is connected to the probe card to transmit the electrical signal and that is connected to the optical probe to transmit the optical signal.

An aspect 17 of one or more embodiments may be the semiconductor wafer testing system of the aspect 16, wherein the semiconductor wafer testing apparatus may comprise the semiconductor wafer handling apparatus of any one of the aspects 1 to 15.

According to one or more embodiments, the optical probe inputs and outputs the optical signal to and from the optical connection part disposed on the second surface of the semiconductor wafer. Therefore, it is possible to provide the semiconductor wafer handling apparatus and the semiconductor wafer testing system for testing the DUT including the electrical circuit and the optical circuit.

### BRIEF DESCRIPTION OF THE DRAWINGS

FIG. 1 is a diagram showing the overall configuration of the semiconductor wafer testing system and the internal structure of the prober in one or more embodiments.

FIG. 2 is a cross-sectional view of the thermal head and optical probe unit and a block diagram showing the control system in one or more embodiments.

FIG. 3A is a plan view of the holding member in one or more embodiments.

FIG. 3B is a cross-sectional view taken along line IIIB-IIIB in FIG. 3A.

FIG. 4 is a plan view of the thermal head and optical probe unit in one or more embodiments.

FIG. 5A is a cross-sectional view showing a modified example of the thermal head and the optical probe unit in one or more embodiments.

FIG. 5B is a plan view showing the modified example of the thermal head and the optical probe unit in one or more embodiments.

FIG. 6 is a cross-sectional view showing the probe card, the thermal head and the optical probe unit in one or more embodiments.

FIG. 7A is a cross-sectional view showing the method of pressing the semiconductor wafer against the probe card by the prober in one or more embodiments.

FIG. 7B is a cross-sectional view showing the method of pressing the semiconductor wafer against the probe card by the prober in one or more embodiments.

FIG. 7C is a cross-sectional view showing the method of pressing the semiconductor wafer against the probe card by the prober in one or more embodiments.

FIG. 8 is a diagram showing the overall configuration of the semiconductor wafer testing system and the internal structure of the prober in one or more embodiments.

### DESCRIPTION OF THE EMBODIMENTS

Hereinafter, embodiments will be described with reference to the drawings.

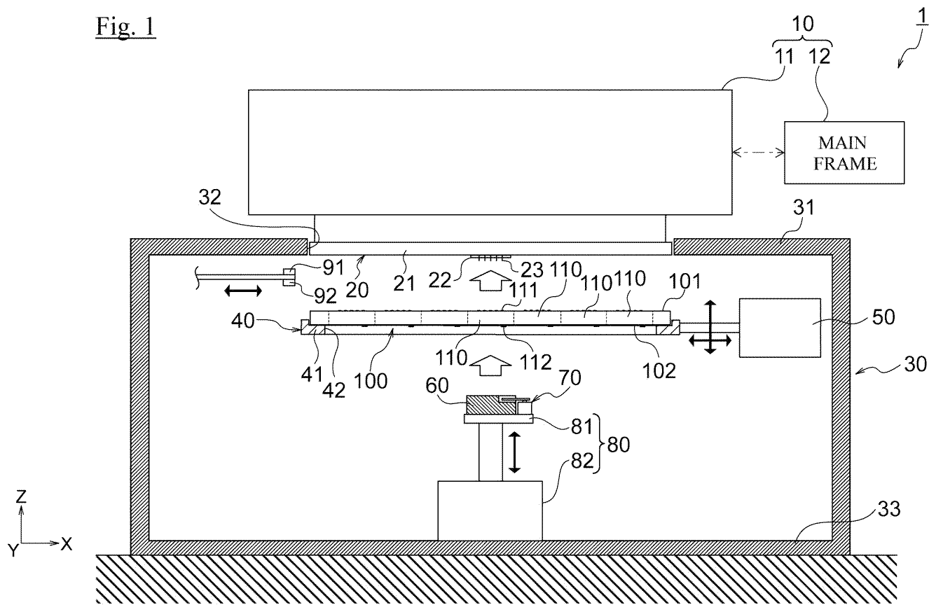

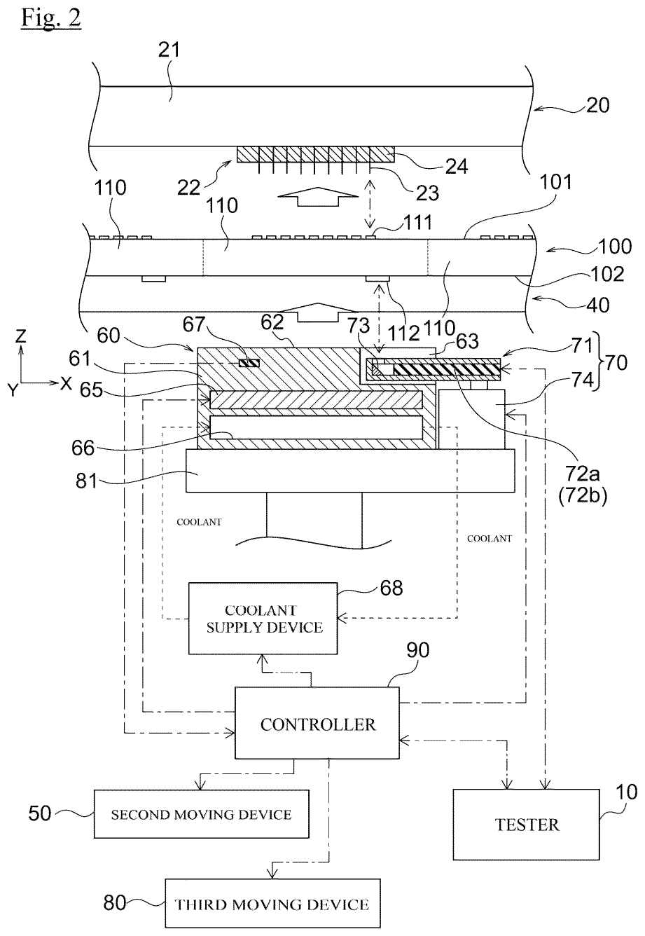

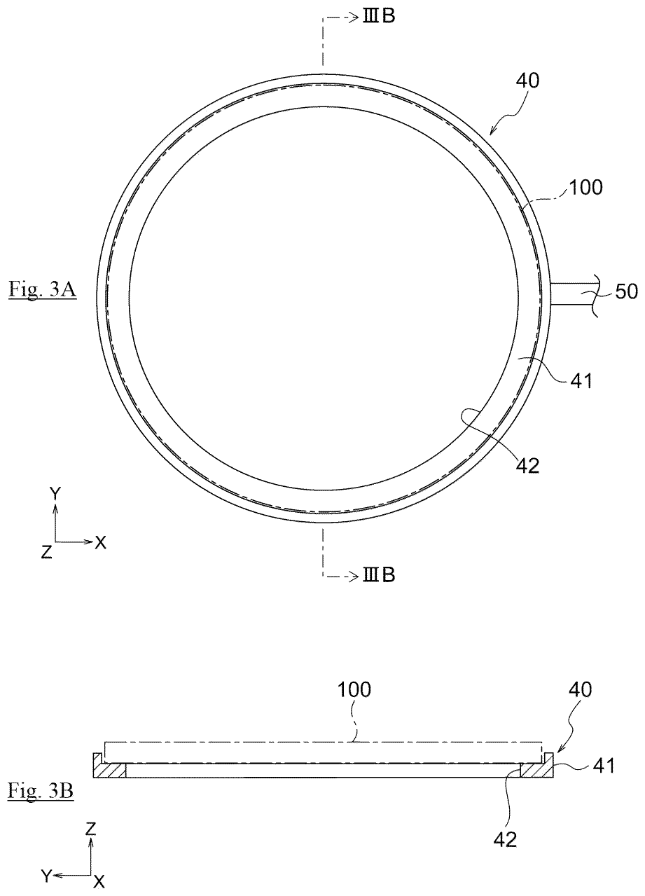

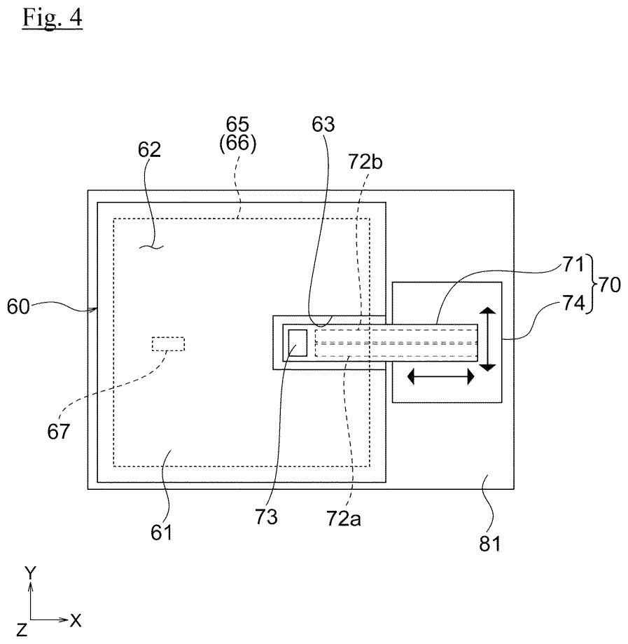

FIG. 1 is a diagram showing the overall configuration of the semiconductor wafer testing system 1 and the internal structure of the prober 30 in one or more embodiments. FIG. 2 is a cross-sectional view of the thermal head 60 and optical probe unit 70 and a block diagram showing the control system in one or more embodiments. FIG. 3A and FIG. 3B are plan and cross-sectional views showing the holding member 40 in one or more embodiments. FIG. 4 is a plan view of the thermal head 60 and optical probe unit 70 in one or more embodiments.

The semiconductor wafer testing system 1 in one or more embodiments is a system that tests a DUT 110 formed in the semiconductor wafer 100. As shown in FIG. 1, the semiconductor wafer testing system 1 includes a tester 10, a probe card 20, and a prober 30. The prober 30 corresponds to an example of the “semiconductor wafer handling apparatus” in one or more embodiments.

The plurality of the DUTs 110 are formed in the semiconductor wafer 100. Each of the DUTs 110 that is the test target of the semiconductor wafer testing system 1 is a device capable of handling electrical and optical signals. That is, the DUT 110 is a hybrid circuit device including an electronic circuit and an optical circuit. The optical circuit is formed using, for example, silicon photonics technology. The DUT 110 includes a terminal 111 for inputting and outputting an electrical signal and an optical connection part 112 for inputting and outputting an optical signal. Although not particularly limited, for example, a grating coupler can be exemplified as a specific example of the optical connection part 112. While the terminal 111 is disposed on the upper surface (first surface) 101 of the semiconductor wafer 100, the optical connection part 112 is disposed on the lower surface (second surface) 102 of the semiconductor wafer 100.

During the test of the DUT 110, an electrical signal is input and output to and from the DUT 110 via the terminal 111, and an optical signal is input and output to and from the DUT 110 via the optical connection part 112. When the test is completed, for example, the DUT 110 is individualized by dicing the semiconductor wafer 100, and the individualized DUT 110 is mounted on a board to which an optical fiber and like is connected to form a final product. This final product is, for example, a CPO (Co-Packaged Optics) device.

The tester 10 is a test apparatus that tests the DUT 110 formed in the semiconductor wafer 100 using electrical and optical signals. As shown in FIG. 1, the tester 10 includes a test head 11 and a main frame (tester body) 12. The test head 11 is connected to the main frame 12 via a cable. The probe card 20 is electrically connected to the test head 11. The probe card 20 enters the inside of the prober 30 through an opening 32 formed in an upper base 31 of the prober 30. The probe card 20 is relatively fixed to the prober 30.

The probe card 20 includes a wiring board 21 and a probe head 22 mounted on wiring board 21. The probe head 22 corresponds to one DUT 110 on the semiconductor wafer 100. As shown FIG. 2, the probe head 22 includes a plurality of probes 23 and a housing 24. The probe 23 corresponds to an example of the “contactor” in one or more embodiments.

The probe 23 is an electrical probe that contacts the terminal 111 of the DUT 110 of the semiconductor wafer 100. The plurality of probes 23 are disposed to correspond to the plurality of terminals 111 included in one DUT 110 on the semiconductor wafer 100. Although not particularly limited, for example, a pogo pin, a vertical probe needle, a cantilever-type probe needle, an anisotropic conductive rubber sheet, a bump provided on a membrane, or a contactor manufactured using MEMS technology can be exemplified as a specific example of the probe 23.

The probes 23 are held by the housing 24, and the probe head 22 is mounted to the wiring board 21 by fixing the housing 24 to the wiring board 21 by screws or the like. The wiring board 21 may directly hold the probes 23, and the housing 24 can be omitted in this case.

As shown FIG. 1 and FIG. 2, the prober 30 includes a holding member 40, a second moving device 50, a thermal head 60, an optical probe unit 70, a third moving device 80, and a controller 90.

In one or more embodiments, the semiconductor wafer 100 held by the holding member 40 is aligned (positioned) with respect to the probe card 20 by the second moving device 50. Further, the thermal head 60 is brought into contact with the lower surface 102 of the semiconductor wafer 100 by the third moving device 80, and the temperature of the DUT is adjusted by the thermal head 60. Then, the semiconductor wafer 100 is pressed against the probe card 20 by the second and third moving devices 50 and 80 to electrically connect the semiconductor wafer 100 and the probe card 20. In this state, the optical probe 71 is aligned (positioned) with respect to the optical connection part 112 of the DUT 110 by the optical probe unit 70, and then, the tester 10 inputs and outputs electrical signals to and from the DUT 110 via the probe card 20 and inputs and outputs optical signals to and from the DUT 110 via the optical connection part 112 to test the DUT 110.

The holding member 40 is a member that holds the semiconductor wafer 100. The holding member 40 holds the lower surface (second surface) 102 of the semiconductor wafer 100, and the entire upper surface (first surface) 101 of the semiconductor wafer 100 is exposed. As shown in FIG. 3A and FIG. 3B, the holding member 40 includes a circular annular holding part 41. The holding part 41 has an opening 42 with an inner diameter smaller than the outer diameter of the semiconductor wafer 100. Therefore, the holding part 41 holds the outer peripheral part of the lower surface 102 of the semiconductor wafer 100. The part of the lower surface 102 of the semiconductor wafer 100 other than the outer peripheral part (the part of the lower surface 102 of the semiconductor wafer 100 that is more inward than the outer peripheral part) is exposed through the opening 42. The holding member 40 may include a holding mechanism that sucks and holds the outer peripheral part of the semiconductor wafer 100. Alternatively, the holding member 40 may include a holding mechanism that holds the outer peripheral part of the semiconductor wafer 100 by a mechanical clamp.

The second moving device 50 is a device that moves the holding member 40. The second moving device 50 is capable of moving the holding member 40 in XYZ axis directions in the figure and rotating (θz) the holding member 51 around the Z axis. The semiconductor wafer 100 is aligned (positioned) with respect to the probe card 20 by the second moving device 50 so that the plurality of terminals 111 of the DUT 110 respectively face the plurality of probe 23 of the probe head 22. The second moving device 50 is fixed to, for example, the frame of the prober 30. As long as the installing position of the second moving device 50 is a location where the second moving device 50 is relatively fixed to the frame of the prober 30, the installing position of the second moving device 50 is not limited to the above. For example, the second moving device 50 may be fixed to the upper base 31 or lower base 32 of the prober 30.

Although not particularly limited, the second moving device 50 includes, for example, an actuator, a transmission mechanism, and a guide mechanism. Although not particularly limited, for example, a motor including an electric motor (rotary motor, linear motor, etc.), and an electric actuator including the electric motor can be exemplified as a specific example of the actuator. For example, a ball screw mechanism can be exemplified as a specific example of the transmission mechanism. For example, a linear guide mechanism including a guide rail and a block that can slide on the guide rail can be exemplified as a specific example of the guide mechanism.

The thermal head 60 is a temperature adjusting device that contacts the lower surface 102 of the semiconductor wafer 100 and adjusts the temperature of the DUT 110. As shown in FIG. 2, the thermal head 60 includes a contact member 61, a heater 65, a flow path 66, and a temperature sensor 67.

The contact member 61 is a block-shaped member having a flat contact surface 62 that contacts the lower surface 102 of the semiconductor wafer 100. The heater 65 is embedded in the contact member 61. The heater 65 is disposed inside the contact member 61 so that the heater 65 corresponds to the entire area of the contact surface 62. Although not particularly limited, a ceramic heater such as an aluminum nitride heater, a silicon nitride heater, and a PTC heater, a polyimide heater, and a cartridge heater can be exemplified as a specific example of the heater 65. The heater 65 is connected to the controller 90. The heater 65 generates heat by power supplied from the controller 90 and heats the DUT 110 via the contact member 61.

The flow path 66 through which a coolant having a temperature lower than room temperature passes is formed inside the contact member 61. The flow path 66 is also disposed inside the contact member 61 so that the flow path 66 corresponds to the entire area of the contact surface 62. A coolant supply device 68 is connected to the flow path 66. As the coolant that is supplied from the coolant supply device 68 passes through the flow path 66, the DUT 110 is cooled via the contact member 61. A liquid or a gas may be used as the coolant flowing through the flow path 66. Although not particularly limited, for example, water and fluorine-based inert liquid can be exemplified as a specific example of a liquid coolant. On the other hand, for example, air and nitrogen can be exemplified as a specific example of gas coolant.

The configuration of the temperature adjusting device that adjusts the temperature of the DUT 110 is not limited to the above. For example, instead of a heater, a hot medium having a temperature higher than room temperature may be passed through a flow path in the contact member 61. Alternatively, a Peltier element may be used as the heater, or a Peltier element may be used instead of the coolant. The temperature adjusting device may not include either a heating device or a cooling device. The contact member 61 may not include the temperature adjusting device.

The temperature sensor 67 is also embedded in the contact member 61. The temperature sensor 67 is disposed inside the contact member 61 so that the temperature sensor 67 is located near the contact surface 62. The temperature sensor 67 detects the temperature of the DUT 110 via the contact surface 62. The temperature sensor 67 is connected to the controller 90 so that the temperature sensor 67 can output the detection result to the controller 90.

As shown in FIG. 2 and FIG. 4, the optical probe unit 70 includes an optical probe 71 and a first moving device 74. The optical probe 71 is an optical input/output part for inputting and outputting optical signals to and from the optical connection part 112 formed on the lower surface 102 of the semiconductor wafer 100. The optical probe 71 includes optical fibers 72a and 72b and a mirror 73.

Each of the optical fibers 72a and 72b is disposed so that the optical axis thereof is along the XY plane in the figure, and the pair of optical fibers 72a and 72b are disposed in substantially parallel. The optical fibers 72a and 72b are connected to the tester 10 to transmit optical signals. The mirror 73 is disposed on the optical axes of the optical fibers 72a and 72b.

When testing the DUT 110, in a state where the end of the optical probe 71 faces the optical connection part 112 of the semiconductor wafer 100, an optical signal input from the tester 10 is output from one optical fiber 72a toward the mirror 73, and the optical signal is reflected by the mirror 73 and is input to the optical connection part 112 of the semiconductor wafer 100. On the other hand, an optical signal output from the optical connection part 112 of the semiconductor wafer 100 is reflected by the mirror 73 and is input to the tester 10 via the other optical fiber 72b. That is, in one or more embodiments, one optical fiber 72a functions as an optical transmission path for input, and the other optical fiber 72b functions as an optical transmission path for output.

In one or more embodiments, although the optical probe 71 inputs and outputs optical signals in a non-contact state with the optical connection part 112 of the semiconductor wafer 100, the optical probe 71 and the optical connection part 112 may be in contact with each other. The optical probe 71 may include optical elements other than the optical fibers 72a and 72b and the mirror 73 as an optical transmission path for transmitting optical signals.

The optical probe 71 is supported by a first moving device 74. The first moving device 74 is an alignment device that aligns (positions) the optical probe 71 with respect to the optical connection part 112 of the semiconductor wafer 100. That is, in one or more embodiments, the alignment (positioning) of the optical probe 71 with respect to the optical connection part 112 can be performed independently of the alignment (positioning) of the terminal 111 of the DUT 110 with respect to the electric probe 23 of the probe card 20. The first moving device 74 is capable of moving the optical probe 71 in the X and Y axis directions in the figure and rotating (θz) the optical probe 71 around the Z axis. The degree of freedom of the first moving device 74 may be six degrees of freedom including the movement in the Z axis direction and the rotations (θx and θy) around the X and Y axes in addition to the above three degrees of freedom.

Although not particularly limited, the first moving device 74 includes, for example, an actuator, a transmission mechanism, and a guide mechanism. Although not particularly limited, for example, a motor including an electric motor (rotary motor, linear motor, etc.), and an electric actuator including the electric motor and a piezoelectric actuator (actuator using a piezoelectric element) can be exemplified as a specific example of the actuator. For example, a ball screw mechanism can be exemplified as a specific example of the transmission mechanism. For example, a linear guide mechanism including a guide rail and a block that can slide on the guide rail can be exemplified as a specific example of the guide mechanism.

The third moving device 80 is a device that moves the thermal head 60 and the optical probe unit 70. As shown in FIG. 1, the third moving device 80 includes a support member 81 and a lifting mechanism 82 that moves the support member 81 in the Z axis direction.

The thermal head 60 and the optical probe unit 70 are supported by a flat support member 81. Specifically, as shown in FIG. 2 and FIG. 4, the contact member 61 of the thermal head 60 and the first moving device 74 of the optical probe unit 70 are fixed to the support member 81. Therefore, the first moving device 74 is capable of relatively moving the optical probe 71 with respect to the thermal head 60.

A groove 63 is formed in the contact member 61 of the thermal head 60. The groove 63 is formed in the contact member 61 so that the groove 63 opens to the contact surface 62 that contacts the semiconductor wafer 100. The optical probe 71 is inserted in the groove 63. A space is secured between the optical probe 71 and the groove 63 so that the optical probe 71 can be moved and rotated by the first moving device 74 described above.

It is possible to increase the contact area of the thermal head 60 with the semiconductor wafer 100 while the optical probe 71 faces the optical connection part 112 of the semiconductor wafer 100 by mutually overlapping the contact member 61 and the optical probe 71. As a result, the DUT 110 can be stably pressed against the probe card 20, and the temperature of the DUT 110 can be efficiently adjusted by the thermal head 60. The groove 63 corresponds to an example of the “recess” in one or more embodiments.

As shown in FIG. 1, the lifting mechanism 82 is installed on the lower base 33 of the prober 30 so that the support member 81 faces the probe head 22 of the probe card 20 in the Z axis direction in the figure. When the lifting mechanism 82 raises the support member 81, the thermal head 60 contacts the lower surface 102 of the semiconductor wafer 100, and the end of the optical probe 71 of the optical probe unit 70 faces the optical connection part 112 of the semiconductor wafer 100. The third moving device 80 is a moving device independent of the above-described second moving device 50 and is capable of moving the thermal head 60 and the optical probe unit 70 independently of the holding member 40.

Although not particularly limited, the lifting mechanism 82 includes, for example, an actuator, a transmission mechanism, and a guide mechanism. Although not particularly limited, for example, a motor including an electric motor (rotary motor, linear motor, etc.), and an electric actuator including the electric motor can be exemplified as a specific example of the actuator. For example, a ball screw mechanism can be exemplified as a specific example of the transmission mechanism. For example, a linear guide mechanism including a guide rail and a block that can slide on the guide rail can be exemplified as a specific example of the guide mechanism.

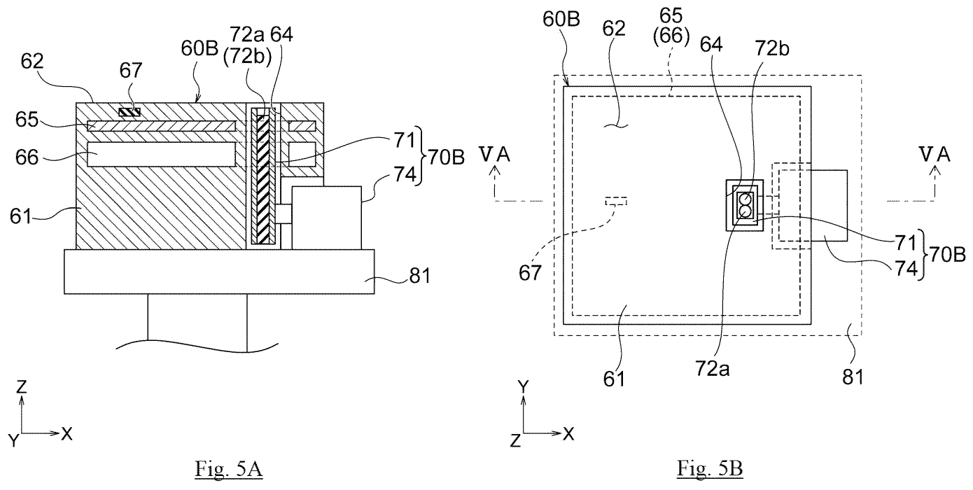

The configuration of the thermal head and the optical probe unit is not limited to the above. For example, the thermal head and the optical probe unit may be configured as shown in FIG. 5A and FIG. 5B. FIG. 5A and FIG. 5B are cross-sectional and plan views showing a modified example of the thermal head and the optical probe unit in one or more embodiments. FIG. 5A is a cross-sectional view along the line VA-VA in FIG. 5B.

In the thermal head 60B and the optical probe unit 70B shown in FIG. 5A and FIG. 5B, an insertion hole 64 is formed in the contact member 61 along the Z axis direction so that the insertion hole 64 opens to the contact surface 62. The optical probe 71 is inserted in the insertion hole 64. In the modified example, the optical probe 71 does not include a mirror 73 because the optical axes of the optical fibers 72a and 72b are disposed in the Z axis direction in the figure. A space is secured between the optical probe 71 and the insertion hole 64 so that the optical probe 71 can be moved and rotated by the first moving device 74. Thus, it is possible to increase the contact area of the thermal head 60 with the semiconductor wafer 100 while the optical probe 71 faces the optical connection part 112 of the semiconductor wafer 100 by disposing the optical probe 71 in the insertion hole 64 formed in the contact member 61.

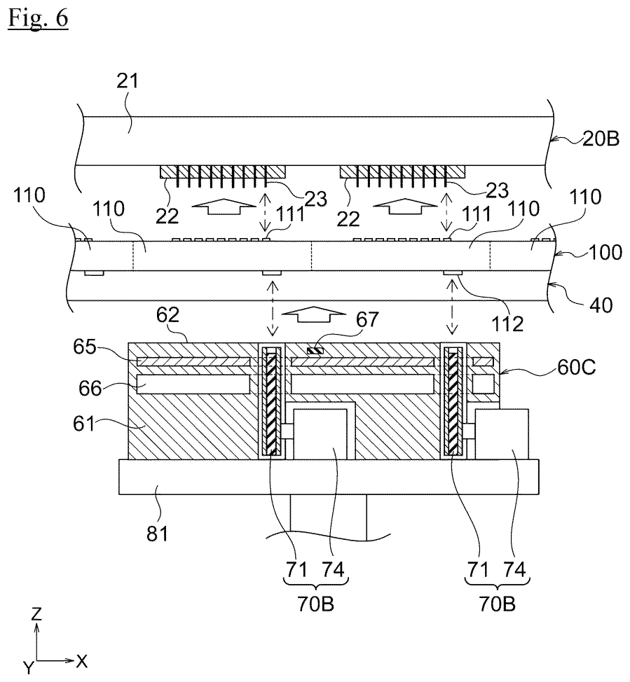

Although only one DUT 110 is tested in one touchdown in the above-described embodiments, a plurality of DUTs 110 may be simultaneously tested in one touchdown. FIG. 6 is a cross-sectional view showing the probe card 20B, the thermal head 60C and the optical probe unit 70B in one or more embodiments.

For example, as shown in FIG. 6, the case of simultaneously testing two DUTs 110 in one touchdown will be described. In this case, the probe card 20B includes two probe heads 22 disposed on the wiring board 21 to correspond to the two DUTs 110. Furthermore, the contact surface 62 of the thermal head 60C has a size capable of contacting the area corresponding to the two DUTs 110 in the lower surface 102 of the semiconductor wafer 100, and it is possible to adjust the temperature of the two DUTs 110 by one thermal head 60C. On the other hand, two optical probe units 70B are disposed on the support member 81 of the third moving device 80 to correspond to the two DUTs 110. Each of the optical probe units 70B includes an optical probe 71 and a first moving device 74, similar to the above-described optical probe unit 70B. The thermal head 60C and the two optical probe units 70B are disposed on the same support member 81.

Instead of the thermal head 60C, two thermal heads 60B may be disposed on the support member 81 to correspond to the two DUTs 110. In the example shown in FIG. 6, the optical probe unit 70 shown in FIG. 2 and FIG. 4 may be used instead of the optical probe unit 70B.

Although not particularly limited, the number N of DUTs 110 that are simultaneously tested in one touchdown is preferably a natural number greater than or equal to 1 and less than or equal to 8 (1≤N≤8). In this case, the probe card includes the N probe heads 22, and the contact surface 62 of the thermal head has a size capable of contacting the N DUTs 110 among all of the DUTs 110 formed on the semiconductor wafer 100, and the thermal head and the N optical probe units are disposed on the same support member 81.

Here, the optical probe unit 70 is required for each DUT 110. Therefore, because the above number N is not the number of all of the DUTs 110 included in the semiconductor wafer 100 and is less than or equal to 8, it is possible to limit the increase in the number of optical probe units 70. Because the above number N is less than or equal to 8, it is sufficient to locally adjust the temperature of the semiconductor wafer 100 by the thermal head 60, and it is also possible to speed up the temperature adjustment of the DUT 110. It is more preferable that the number N is a natural number greater than or equal to 1 and less than or equal to 4 (1≤N≤4), and even more preferable that it is a natural number greater than or equal to 1 and less than or equal to 2 (1≤N≤2). The number of all of the DUTs 110 included in the semiconductor wafer 100 is greater than the above number N.

The contact surface 62 of the thermal head may have a size capable of contacting all of the DUTs 110 included in the semiconductor wafer 100. The above number N may be the number of all of the DUTs 110 included in the semiconductor wafer 100.

Returning to FIG. 2, the controller 90 includes, for example, a computer. Although not specifically shown, the computer is an electronic computer that includes a CPU (processor), a main memory (such as a RAM), an auxiliary memory device (such as a hard disk or SSD), an interface, and the like. The control described below is functionally realized, for example, by the controller 90 executing a program. The controller 90 may be configured with a circuit board instead of a computer.

As shown in FIG. 2, the controller 90 is electrically connected to the heater 65, the temperature sensor 67, and the coolant supply device 68. The controller 90 controls the heater 65 and the coolant supply device 68 based on the detection result of the temperature sensor 67 to adjust the temperature of the DUT 110 through the contact member 61. The controller 90 may control the heater 65 and the coolant supply device 68 based on the output of the temperature detecting circuit formed in the semiconductor wafer 100 instead of the temperature sensor 67. Although not particularly limited, for example, a circuit including a thermal diode and formed in the semiconductor wafer 100 can be exemplified as a specific example of the temperature detecting circuit.

The controller 90 is connected to the tester 10 so that the controller 90 is capable of transmitting electrical signals to and from the tester 10. The tester 10 has the function to test the electronic circuit of the DUT 110 and the function to test the optical circuit of the DUT 110. The tester 10 is connected to the optical fibers 72a and 72b of the optical probe 71 so that the tester 10 is capable of transmitting optical signals to and from the optical fibers 72a and 72b of the optical probe 71. The function to test the optical circuit of the DUT 110 includes the function of the light source and the function to measure the intensity of light. The controller 90 is connected to the first to third moving devices 74, 50 and 80 so that the controller 90 is capable of outputting control signals to the first to third moving devices 74, 50 and 80. The controller 90 can control the operation of the moving devices 74, 50 and 80. The tester 10 may not have the function to test the optical circuit of the DUT 110. In this case, an external measuring device having the function to test the optical circuit of the DUT 110 is connected to the optical fibers 72a and 72b of the optical probe 71 so that the external measuring device is capable of transmitting optical signals to and from the optical fibers 72a and 72b of the optical probe 71. The external measuring device is a testing device independent of the tester 10 and is, for example, electrically connected to the tester 10.

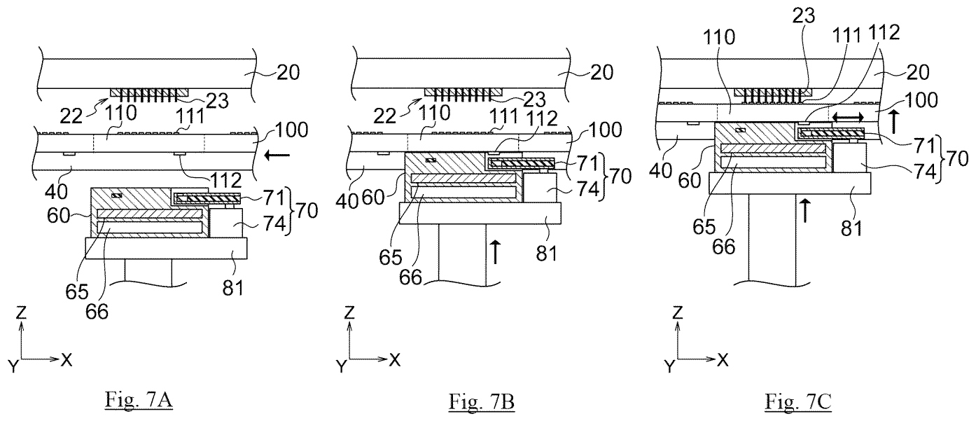

Below, the method of pressing the semiconductor wafer 100 against the probe card 20 by the above-described prober 30 will be explained with reference to FIG. 7A to FIG. 7C. FIG. 7A to FIG. 7C are cross-sectional views showing the method of pressing the semiconductor wafer 100 against the probe card 20 by the prober 30 in one or more embodiments.

First, as shown in FIG. 7A, the second moving device 50 moves the holding member 40 so that the semiconductor wafer 100 held by the holding member 40 faces the probe card 20. At this time, the position of the holding member 40 is finely adjusted by the second moving device 50, and the semiconductor wafer 100 is aligned (positioned) with respect to the probe card 20 so that the plurality of terminals 111 of the DUT 110 respectively face the plurality of probes 23 of the probe head 22.

The relative positional relationship between the terminals 111 of the semiconductor wafer 100 and the probes 23 of the probe card 20 is recognized in advance by, for example, the cameras 91 and 92 (refer to FIG. 1) and the image processing function of the controller 90. Specifically, the cameras 91 and 92 can be moved by a moving device not shown in the figures. The camera 91 captures the image of the probe card 20, and another camera 92 captures the image of the semiconductor wafer 100 held by the holding member 40. Then, the relative positional relationship between the terminals 111 and the probes 23 is recognized based on these images by the image processing function of the controller 90. Although not shown in the figures, the semiconductor wafer 100 is supplied to the holding member 40 from a cassette such as a FOUP (Front-Opening Unified Pod) by a transfer arm.

Next, as shown in FIG. 7B, the third moving device 80 raises the thermal head 60 and the optical probe unit 70 to bring the thermal head 60 into contact with the semiconductor wafer 100 held by the holding member 40. At this time, because the outer peripheral part of the semiconductor wafer 100 is held by the holding member 40, the contact surface 62 of the thermal head 60 directly contacts the exposed part of the lower surface 102 of the semiconductor wafer 100 that is more inward than the outer peripheral part. When the thermal head 60 contacts the semiconductor wafer 100, the controller 90 starts controlling the heater 65 and the coolant supply device 68 to adjust the temperature of the DUT 110.

Next, as shown in FIG. 7C, while maintaining the contact state between the thermal head 60 and the semiconductor wafer 100, the second moving device 50 raises the holding member 40, the third moving device 80 raises the thermal head 60 and the optical probe unit 70, and the semiconductor wafer 100 is pressed against the probe card 20 to electrically connect the semiconductor wafer 100 and the probe card 20. In this state, the plurality of terminals 111 of the DUT 110 are in contact with the plurality of probes 23 of the probe card 20.

Next, the first moving device 74 relatively aligns (positions) the end of the optical probe 71 with respect to the optical connection part 112 of the semiconductor wafer 100 by finely adjusting the position of the optical probe 71. Although not particularly limited, the positional relationship between the optical probe 71 and the optical connection part 112 is recognized based on, for example, the intensity of light output from the optical connection part 112.

Specifically, light output from the light source included in the tester 10 is irradiated from the one optical fiber 72a of the optical probe 71 toward the lower surface 102 of the semiconductor wafer 100 including the optical connection part 112. Then, the other optical fiber 72b receives the light output from the optical connection part 112 via a loopback circuit incorporated in the optical circuit of the DUT 110. While this operation is being performed, the first moving device 74 causes the optical probe 71 to scan along the lower surface 102 of the semiconductor wafer 100. Then, the tester 10 measures the intensity of light output from the optical connection part 112, and the controller 90 stops the movement of the optical probe 71 at a position where the intensity of light is equal to or greater than a predetermined value. As a result, the optical probe 71 is aligned (positioned) with respect to the optical connection part 112.

As with the relative positional relationship between the terminal 111 of the semiconductor wafer 100 and the probe 23 of the probe card 20 described above, the relative positional relationship between the optical probe 71 and the optical connection part 112 may be recognized by cameras and an image processing. In this case, for example, the semiconductor wafer 100 held by the holding member 40 is imaged from below with a camera and the thermal head 60 is imaged from above with another camera before the thermal head 60 contacts the semiconductor wafer 100 held by the holding member 40. Then, the image processing function of the controller 90 recognizes the relative positional relationship between the optical probe 71 and the optical connection part 112 based on these images. Alternatively, the optical probe 71 may be coarsely aligned with respect to the optical connecting part 112 using image processing, and then the optical probe 71 may be precisely aligned based on the intensity of light.

The alignment of the optical probe 71 with respect to the optical connection part

112 may be performed in a state where the thermal head 60 is in contact with the semiconductor wafer 100 held by the holding member 40 (the state shown in FIG. 7B). That is, the alignment of the optical probe 71 with respect to the optical connection part 112 may be performed before electrically connecting the semiconductor wafer 100 and the probe card 20.

Next, the tester 10 inputs an electrical signal to the DUT 110 via the electrical probe 23 and the terminal 111, and the tester 10 also inputs an optical signal to the DUT 110 via the optical probe 71 and the optical connection part 112. Then, the tester 10 determines the quality and characteristics of the DUT 110 based on the electrical signal output from the DUT 110 via the terminal 111 and the electrical probe 23 and the optical signal output from the DUT 110 via the optical connection part 112 and optical probe 71.

In one or more embodiments, because an optical signal can be input and output to and from the optical connection part 112 disposed on the lower surface 102 of the semiconductor wafer 100 by the optical probe 71, it is possible to test the DUT 110 including the electronic and optical circuits. In particular, in one or more embodiments, it is possible to test the DUT 110 that has a terminal 111 disposed on one surface 101 of the semiconductor wafer 100 and an optical connection part 112 disposed on the other surface 102 of the semiconductor wafer 100.

Further, in one or more embodiments, the prober 30 includes the first moving device 74 that moves the optical probe 71 independently of the second moving device 50 that aligns the semiconductor wafer 100 with respect to the probe card 20. Therefore, it is possible to relatively align (position) the optical probe 71 with respect to the optical connection part 112 of the DUT 110 in a state where the semiconductor wafer 100 is held by the holding member 40. Further, even if the accuracy of the alignment of the optical probe 71 with respect to the optical connection part 112 is higher than that of the electrical probe 23 with respect to the terminal 111, it is possible to align the optical probe 71 with respect to the optical connection part 112 with high accuracy by the first moving device 74.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

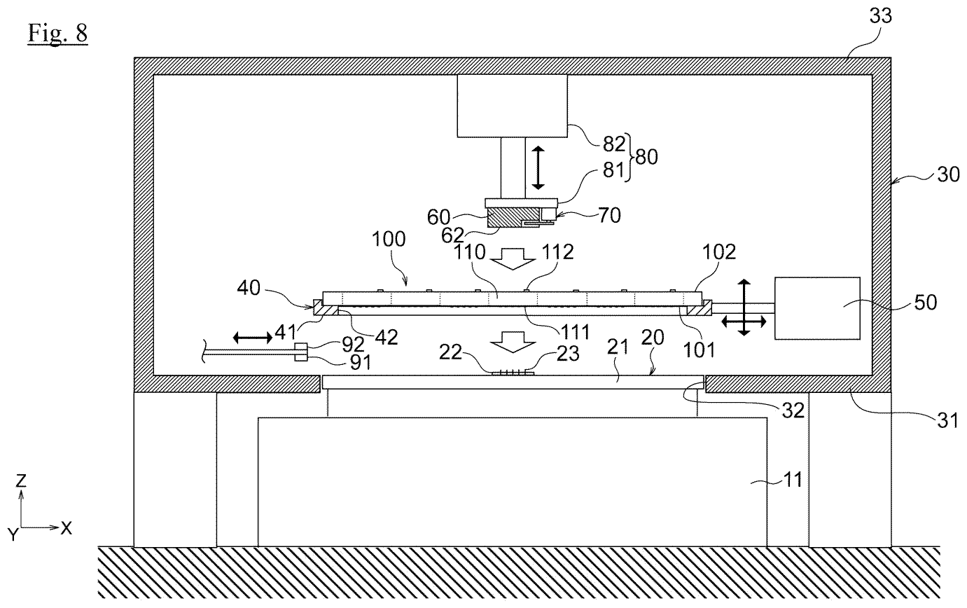

For example, as shown in FIG. 8, the semiconductor wafer testing system 1 may be configured to test the semiconductor wafer 100 in a posture opposite in the vertical direction to that of the above-described embodiments. FIG. 8 is a diagram showing the overall configuration of the semiconductor wafer testing system and the internal structure of the prober in one or more embodiments.

In this case, as shown in FIG. 8, the annular holding part 41 of the holding member 40 holds the lower surface (first surface) 101 of the semiconductor wafer 100. The upper surface (second surface) 102 of the semiconductor wafer 100 faces upward, and the entire upper surface 102 is exposed. The probe card 20 is disposed below the holding member 40 with the probes 23 facing upward, and the second moving device 80 is disposed above the holding member 40 with the contact surface 62 of the thermal head 60 and the optical axis of the optical probe unit 70 facing downward. That is, in one or more embodiments shown in FIG. 8, all the components except for the holding member 40 are inverted from the above-mentioned embodiments.

### EXPLANATIONS OF LETTERS OR NUMERALS

1 . . . Semiconductor wafer testing system
10 . . . Tester
11 . . . Test head
12 . . . Main frame
20 . . . Probe card
21 . . . Wiring board
22 . . . Probe head
23 . . . Probe (contactor)
24 . . . Housing
30 . . . Prober
31 . . . Upper base
32 . . . Opening
33 . . . Lower base
40 . . . Holding member
41 . . . Holding part
42 . . . Opening
50 . . . Second Moving device
60, 60B and 60C . . . Thermal head
61 . . . Contact member
62 . . . Contact surface
63 . . . Groove
64 . . . Insertion hole
65 . . . Heater
66 . . . Flow path
67 . . . Temperature sensor
68 . . . Coolant supply device
70 and 70B . . . Optical probe unit
71 . . . Optical probe
72a, 72b . . . Optical fiber
73 . . . Mirror
74 . . . First moving device
80 . . . Third moving device
81 . . . Support member
82 . . . Lifting mechanism
90 . . . Controller
91 and 92 . . . Camera
100 . . . Semiconductor wafer
101 . . . Upper surface
102 . . . Lower surface
110 . . . DUT
111 . . . Terminal
112 . . . Optical connection part

What is claimed is:

1. A semiconductor wafer handling apparatus that moves a semiconductor wafer including a device under test (DUT) and presses a terminal of the DUT against a contactor of a probe card, the semiconductor wafer handling apparatus comprising:
an optical probe that inputs and outputs an optical signal to and from an optical connection part of the DUT, wherein
the terminal is disposed on a first surface of the semiconductor wafer, and
the optical connection part is disposed on a second surface of the semiconductor wafer.

2. The semiconductor wafer handling apparatus according to claim 1, further comprising:
a first moving device that moves the optical probe relative to the semiconductor wafer.

3. The semiconductor wafer handling apparatus according to claim 2, further comprising:
a holding member that holds the semiconductor wafer; and
a second moving device that moves the holding member relative to the probe card, wherein
the first moving device moves the optical probe relative to the semiconductor wafer held by the holding member.

4. The semiconductor wafer handling apparatus according to claim 3, further comprising:
a contact member that contacts the second surface of the semiconductor wafer; and
a third moving device that moves the contact member and the first moving device relative to the semiconductor wafer held by the holding member.

5. The semiconductor wafer handling apparatus according to claim 4, wherein
the contact member comprises:
a contact surface that contacts the second surface of the semiconductor wafer; and
a recess that opens to the contact surface, and
the optical probe is disposed in the recess such that the optical probe moves relative to the contact member.

6. The semiconductor wafer handling apparatus according to claim 4, wherein
the contact member comprises:
a contact surface that contacts the second surface of the semiconductor wafer; and
an insertion hole that opens to the contact surface, and
the optical probe is inserted into the insertion hole such that the optical probe moves relative to the contact member.

7. The semiconductor wafer handling apparatus according to claim 4, wherein
the third moving device comprises a support member to which the contact member and the first moving device are fixed, and
the first moving device moves the optical probe relative to the contact member.

8. The semiconductor wafer handling apparatus according to claim 4, further comprising:
a controller that controls the second and third moving devices such that the holding member and the contact member move toward the probe card in a pressing direction of the DUT against the probe card to press the terminal of the DUT against the contactor of the probe card.

9. A semiconductor wafer handling apparatus that moves a semiconductor wafer including device under tests (DUTs) and presses terminals of the DUTs against contactors of a probe card, the semiconductor wafer handling apparatus comprising:
N optical probes each of which inputs and outputs an optical signal to and from each of a plurality of optical connection parts of the DUTs, respectively where the N is a natural number between 1 and 8, inclusive, wherein
the terminals are disposed on a first surface of the semiconductor wafer,
the optical connection parts are disposed on a second surface of the semiconductor wafer,
the semiconductor wafer handling apparatus further comprises:
a holding member that holds the semiconductor wafer;
N first moving devices each of which moves a corresponding optical probe of the N optical probes relative to the semiconductor wafer held by the holding member;
a second moving device that moves the holding member relative to the probe card;
a contact member that contacts the second surface of the semiconductor wafer,
the contact member comprises a contact surface that contacts the second surface of the semiconductor wafer,
the contact surface has a size such that the contact surface contacts N DUTs of the DUTs,
the N optical probes are disposed to correspond to the N DUTs, and
the N first moving devices that each move a corresponding one of the N optical probes.

10. The semiconductor wafer handling apparatus according to claim 9, further comprising:
a third moving device that moves the contact member and the N first moving devices relative to the semiconductor wafer held by the holding member.

11. The semiconductor wafer handling apparatus according to claim 3, wherein the holding member holds either an outer peripheral part of the first surface of the semiconductor wafer or an outer peripheral part of the second surface of the semiconductor wafer such that the first and second surfaces are exposed.

12. The semiconductor wafer handling apparatus according to claim 3, wherein the holding member comprises an annular holding part that holds either an outer peripheral part of the first surface of the semiconductor wafer or an outer peripheral part of the second surface of the semiconductor wafer.

13. The semiconductor wafer handling apparatus according to claim 1, wherein the optical probe comprises an optical transmission path that transmits the optical signal.

14. The semiconductor wafer handling apparatus according to claim 1, wherein the optical connection part includes a grating coupler.

15. A semiconductor wafer testing system that tests a device under test (DUT) in a semiconductor wafer, comprising:
a probe card that inputs and outputs an electrical signal to and from a terminal of the DUT;
an optical probe that inputs and outputs an optical signal to and from an optical connection part of the DUT; and
a testing device connected to the probe card and the optical probe to transmit the electrical signal and the optical signal, respectively, wherein
the terminal is disposed on a first surface of the semiconductor wafer, and
the optical connection part is disposed on a second surface of the semiconductor wafer.

16. A semiconductor wafer testing system that tests the DUT, comprising:
the semiconductor wafer handling apparatus according to claim 1;
the probe card that inputs and outputs an electrical signal to and from the terminal of the DUT; and
a testing device connected to the probe card and the optical probe to transmit the electrical signal and the optical signal, respectively.
